(19) United States
(12) Patent Application Publication
(10) Pub. No.: US 2006/0006511 A1
(43) Pub. Date: Jan. 12, 2006

(54) Ultrathin module for semiconductor device and method of fabricating the same

(75) Inventors: Kwon-Young Roh, Seoul (KR); Seung-Kon Mok, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(73) Assignee: Samsung Electronics Co., Ltd.

(21) Appl. No.: 11/010,349

(22) Filed: Dec. 14, 2004

(30) Foreign Application Priority Data
Jul. 6, 2004 (KR) 2004-52298

(51) Int. Cl. H01L 23/02; H01L 21/44

(52) U.S. Cl. 257/680; 257/432; 438/116

(57) ABSTRACT

An ultrathin module is provided for special types of semiconductor devices such as image sensor devices and micro-electro-mechanical system (MEMS) devices. In the module, a chip cover is directly attached to a semiconductor chip so as to protect a light-sensing area or mechanical elements of the chip. The chip cover may also be used as a lens assembly and an infrared light filter. In a fabrication method, the chips are provided on a wafer, and the chip covers are attached to the chips, respectively, before the wafer is sliced to separate the chips from one another.

### BACKGROUND OF THE INVENTION

1. Field of the Invention

The present invention relates generally to electronic packaging technology. More particularly, the present invention relates to special types of semiconductor devices, such as image sensor devices and micro-electro-mechanical system (MEMS) devices, and to an ultrathin module comprising such devices.

2. Description of the Related Art

Recently, enhanced imaging technology has produced superior image quality not only for high-resolution camera phones, but also for current and emerging industrial applications that require cost-effective image-capturing solutions. This enhanced imaging technology often resides in an image sensor module. The image sensor module contains an image sensor capable of converting optical images into electric signals.

More specifically, the image sensor comprises an array of pixels, and acquires an image when light is incident on the array of pixels. The pixels change the photons of the incident light into electrons. An image sensor of this type may be generally classified as a charge-coupled device (CCD) or a complementary metal-oxide-silicon (CMOS) image sensor. While the CCD is relatively superior in terms of image quality and noise, the CMOS image sensor costs less to produce and consumes less power.

Such conventional image sensors may be assembled in a bare or packaged form into a module. FIG. 1A shows a conventional packaged form of an image sensor device, and FIG. 1B shows a conventional module in which a packaged form of an image sensor is contained. FIG. 2 shows a conventional module in which a bare form of an image sensor is contained.

Referring to FIG. 1A, the conventional image sensor package 10 has a package substrate 12 on which the image sensor is attached. Such image sensors are fabricated on a wafer and then are separated from one another in the form of chips. The image sensor chip 11 is electrically coupled to the package substrate 12 via metal wires 13. Package terminals 14 are provided outside the package substrate 12 and are electrically coupled to the metal wires 13 via circuit patterns (not shown) in the package substrate 12. A package cover 15 is attached to the top of the package substrate 12, whereby the image sensor chip 11 and the metal wires 13 are protected from the external environment. The package cover 15 is made of material transparent to incident light.

Referring to FIG. 1B, this type of conventional image sensor module 20a includes a module substrate 21 to which the aforementioned image sensor package 10 is attached. The package terminals 14 are electrically coupled to circuit patterns (not shown) on the module substrate 21. A module housing 22 is attached to the module substrate 21, thereby completely covering the package 10. The module housing 22 has a lens assembly 23 and an infrared light filter 24 that lie over the image sensor chip of the package 10.

Referring to FIG. 2, this type of conventional image sensor module 20b includes an image sensor chip 11 directly attached to the module substrate 21 using a chip-on-board (COB) technique. According to this technique, the image sensor chip 11 is directly and electrically coupled to the module substrate 21 via metal wires 13. The module housing 22 covers the image sensor chip 11 and is attached to the module substrate 21. The module housing 22 has a lens assembly 23 and an infrared light filter 24 overlying the image sensor chip 11.

The above-described conventional image sensor modules each require a lens assembly 23 and an infrared rays light filter 24 in order to fulfill their function. However, since the lens assembly 23 and the infrared rays light filter 24 are integrated with the module housing 22, they are necessarily spaced apart from the image sensor chip 11. Accordingly, the image sensor modules are relatively thick, a factor which determines the size and weight of related products, especially mobile appliances.

### SUMMARY OF THE INVENTION

An object of the present invention is to provide an ultrathin module for special semiconductor devices such as image sensor devices and micro-electro-mechanical system (MEMS) devices.

Another object of the present invention is to provide an ultrathin module for special semiconductor devices that is easy to mass produce.

According to one aspect of the present invention, the ultrathin module comprises a semiconductor chip, and a protective chip cover disposed over a specific region of an active surface of the chip. The specific region is located at a central portion of the active surface thereof. The semiconductor chip may comprise an image sensor wherein the specific region of the chip is a light-sensing area. Alternatively, the semiconductor chip may comprise a micro-electro-mechanical system (MEMS) device in which mechanical elements occupy the specific region of the active surface of the chip. A plurality of input/output pads are disposed along the periphery of the active surface. The chip cover has a cavity provided in a central part of a lower surface thereof. The cavity covers the specific region of the active surface of the semiconductor chip, but the lower surface does not cover the input/output pads.

The ultrathin module may further comprise a module substrate supporting the semiconductor chip and to which the chip is directly attached and electrically coupled. The module substrate may be a printed circuit board, a lead frame, a ceramic substrate or a circuit film.

According to another aspect of the invention, the chip cover may be made of transparent material such as glass, transparent resin, or a transparent metal oxide. The chip cover may contain or be coated with metal ions. Alternatively, the chip cover may be made of translucent or opaque material such as plastic or ceramics. Also, the chip cover may be fabricated to act as a lens assembly and/or an infrared light filter.

According to yet another aspect of the invention, the ultrathin module may further comprise a body of plastic resin enveloping the semiconductor chip. In this case, an upper surface of the chip cover is left exposed at the outside of the body of plastic resin. Alternatively, the module may further comprise a module housing covering the semiconductor chip, attached to the module substrate, and having a lens assembly lying just above the chip cover.

According to still another aspect of the present invention, a method of fabricating the ultrathin module comprises providing a wafer that includes a number of semiconductor chips, and attaching a chip cover to each of the chips before the wafer is sliced to separate the chips from one another. The chip cover is attached such that the cavity in the lower surface thereof is located over and is open to the specific region of the chip while the input/output pads are left exposed at the outside of the chip cover. Once the chips are separated from each other, the method may further comprise directly attaching and electrically coupling each semiconductor chip to a module substrate.

Also, a molding process can be performed to embed the semiconductor chip in a body of plastic resin while leaving an upper surface of the chip exposed at the outside of the plastic resin. Alternatively, the method may further comprise attaching a module housing, having a lens assembly, to the module substrate so as to cover the semiconductor chip and position the lens assembly just above the chip cover.

### BRIEF DESCRIPTION OF THE DRAWINGS

FIG. 1A is a cross-sectional view of a conventional package comprising an image sensor device.

FIG. 1B is a cross-sectional view of a conventional module which includes the package shown in FIG. 1A.

FIG. 2 is a cross-sectional view of another conventional module which includes a bare form of the image sensor device.

FIG. 3 is a cross-sectional view of an ultrathin module in accordance with the present invention.

FIG. 4 is a cross-sectional view of another embodiment of an ultrathin module in accordance with the present invention.

FIG. 5 is a cross-sectional view of still another still another embodiment of an ultrathin module in accordance with of the present invention.

FIGS. 6A to 9 are diagrams illustrating a method of fabricating an ultrathin module in accordance with the present invention, wherein

FIGS. 6A and 6B are a plan view and a cross-sectional view, respectively, of a wafer including semiconductor device chips,

FIGS. 7A and 7B are a plan view and a cross-sectional view, respectively, of the wafer and show chip covers directly attached to the semiconductor device chips,

FIG. 8 is a cross-sectional view of the wafer and shows the separation of the individual chips, and

FIG. 9 is a cross-sectional view of a separated chip as it is being secured to a module substrate.

FIGS. 10A to 10D are cross-sectional views of modules having different versions of a chip cover in accordance with the present invention.

### DETAILED DESCRIPTION OF THE PREFERRED EMBODIMENTS

The present invention will now be described more fully hereinafter with reference to the accompanying drawings. In this disclosure, well-known structures and processes are not described or illustrated in detail for the sake of clarity. Furthermore, the drawings are not to scale. Rather, the relative dimensions of some of the elements may be exaggerated for simplicity and clarity of illustration. Still further, like reference numerals are used to designate like and corresponding parts throughout the drawings.

Referring now to FIGS. 3 to 5, each ultrathin module 30, 40 and 50 includes a semiconductor chip 31 that is directly attached to a top surface of a module substrate 35 or 45. The semiconductor chip 31 has a number of input/output (I/O) pads 32 disposed along the periphery of on an active surface thereof. Furthermore, the semiconductor chip 31 has a specific region 33 at the center of the active surface that needs protection. Although not shown in drawings, another chip, such as a digital signal processing (DSP) chip, may be provided on the bottom surface of the module substrate 35 or 45.

The semiconductor chip 31 is a special kind of device such as an image sensor device or a micro-electro-mechanical system (MEMS) device. The specific region 33 of the chip 31 is a light-sensing area in the case of an image sensor device, or is occupied by mechanical elements in the case of a MEMS device.

As is known in the art, a MEMS device includes micromechanical components and electronics integrated on a common silicon substrate through micro-fabrication technology. Whereas the electronics are fabricated using integrated circuit (IC) processes, the micromechanical components are fabricated using compatible micromachining processes. Thus, in MEMS devices, unprecedented levels of functionality, reliability, and sophistication can be achieved on a small silicon chip at a relatively low cost.

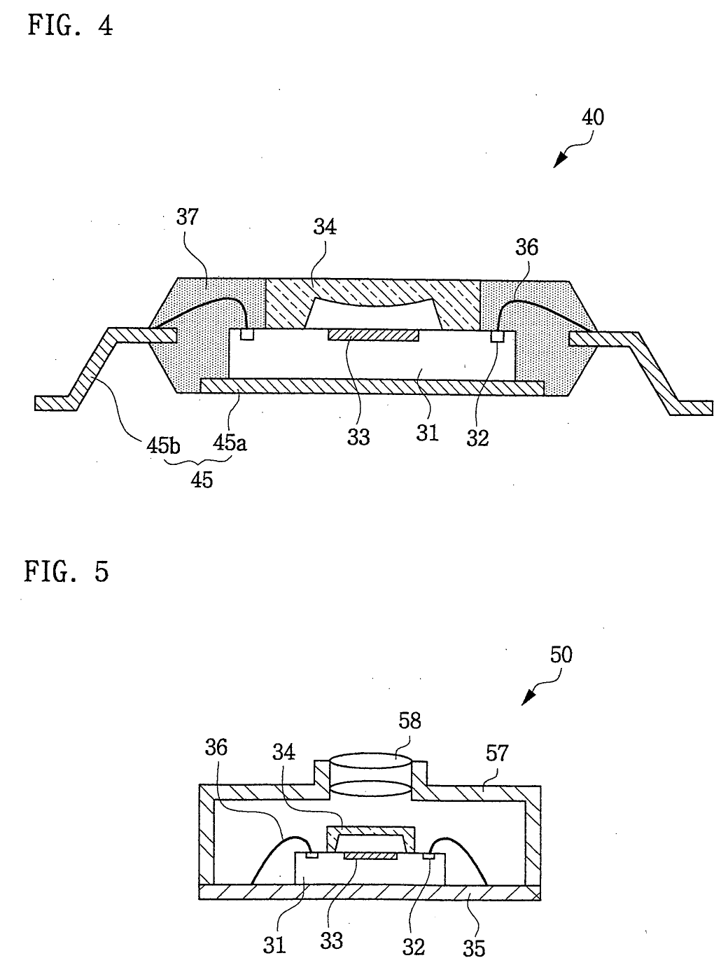

The ultrathin modules 30, 40 and 50 may employ, as the module substrate, a printed circuit board (PCB) 35, as shown in FIGS. 3 and 5, or a lead frame 45, as shown in FIG. 4. However, these module substrates are exemplary only, and other suitable module substrates, such as ceramic substrates or circuit films may be used instead.

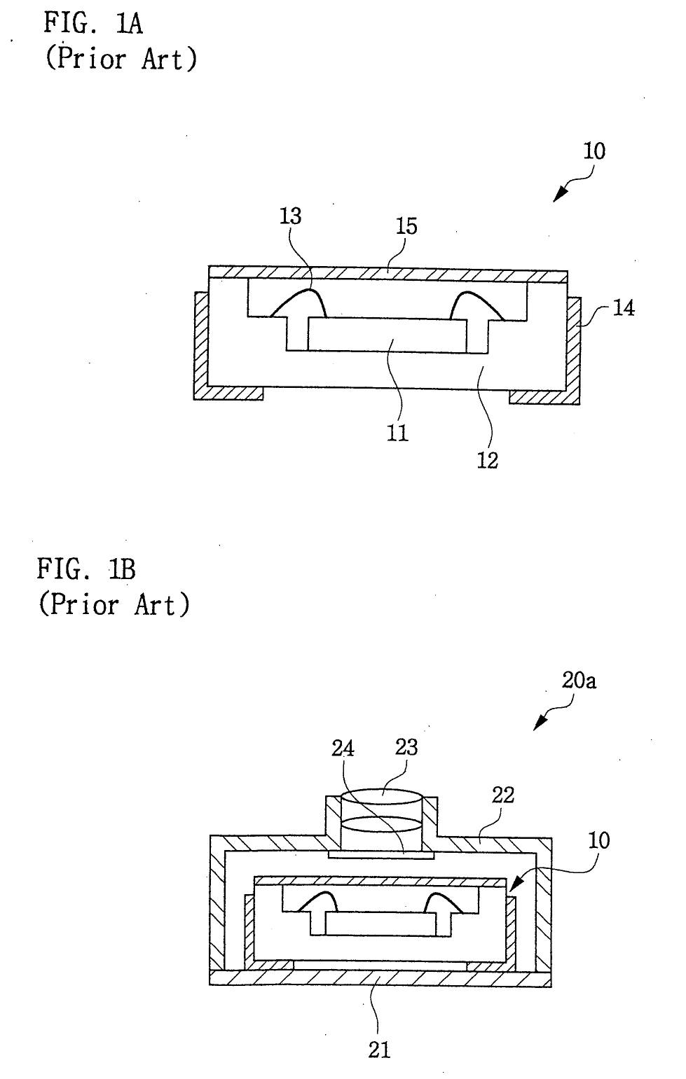

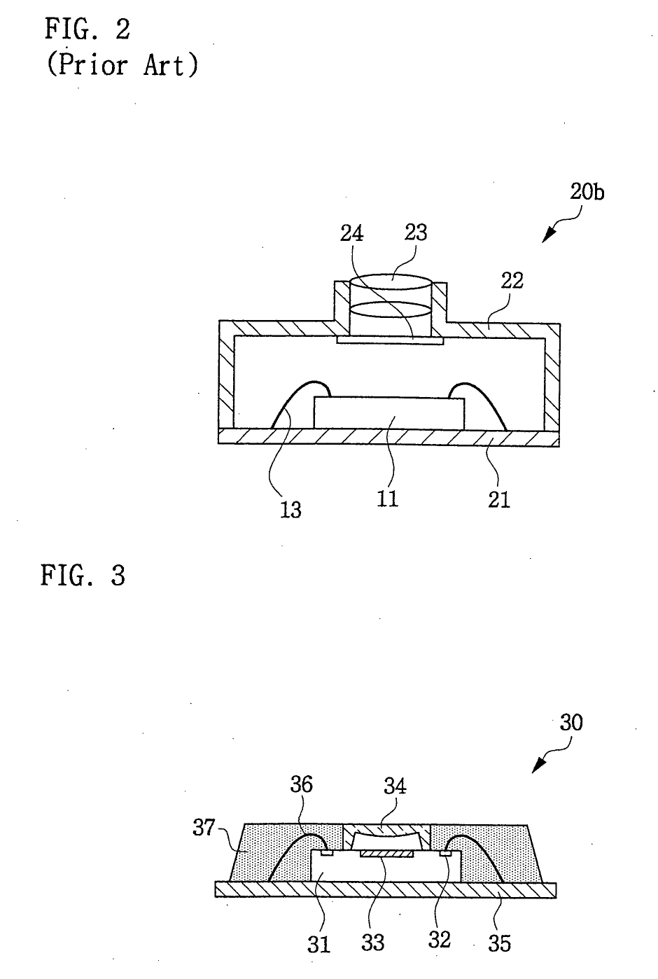

Each ultrathin module 30, 40 and 50 further includes a chip cover 34 that is attached to the top surface of the semiconductor chip 31. The chip cover 34 is laid over the specific region 33 not only to protect the specific region 33 from the external environment (similarly to the conventional package cover 15 shown in FIG. 1A), but also to supersede the conventional infrared rays light filter 24 shown in FIGS. 1B and 2. The chip cover 34 may also supersede the conventional lens assembly 23 shown in FIGS. 1B and 2. For example, in the embodiments of FIGS. 3 and 4, in addition to being a protective cover, the chip cover 34 serves as both a lens assembly and an infrared rays light filter. On the other hand, in the embodiment in FIG. 5, in addition to being a protective cover, the chip cover 34 serves only as an infrared rays light filter.

In the case of an image sensor module, the chip cover 34 may be made of transparent material such as glass, a transparent resin such as an acrylic acid resin or a polyester resin, or a transparent metal oxide such as tin oxide or indium oxide. Furthermore, the chip cover 34 may contain or be coated with metal ions, such as copper or iron ions, to filter infrared rays. In the case of a MEMS device module, the chip cover 34 may be made of translucent or opaque material, such as plastic or ceramics, or may be made of a transparent material.

In the embodiments of FIGS. 3 and 5, the I/O pads 32 of the chip 31 are electrically coupled to circuit patterns (not shown) of the PCB 35 via metal wires 36. In the embodiment of FIG. 4, the chip 31 is mechanically attached to a chip-supporting pad 45a of the lead frame 45 via an adhesive (not shown) and is electrically coupled to lead terminals 45b of the lead frame 45 via the metal wires 36.

Also, in the embodiments of FIGS. 3 and 4, a body of plastic resin 37, formed by a molding process, completely covers the chip 31 and the metal wires 36. However, the chip cover 34 is left exposed by the body of plastic resin 37. The body of plastic resin 37 is easier to mass produce and less costly to manufacture than the conventional module housing 22 shown in FIGS. 1B and 2.

In the embodiment of FIG. 4, the chip-supporting pad 45a of the lead frame may be contained within the plastic resin 37 or exposed to enhance heat dissipation. In an alternative embodiment, the lead frame 45 may have only the lead terminals 45b, i.e., may be provided without the chip-supporting pad 45a. In this case, the bottom surface of the chip 31 may be exposed at the outside of the body of plastic resin 37, and a suitable chip-supporting member, such as an adhesive tape, may be temporarily used until the molding process is completed.

When the chip cover 34 is used as the infrared rays light filter only, as in the embodiment of FIG. 5, the ultrathin module 50 may further include a module housing 57 having a lens assembly 58. The module housing 57 covers the semiconductor chip 31 and is attached to the module substrate 35. The lens assembly 58 lies just above the chip cover 34.

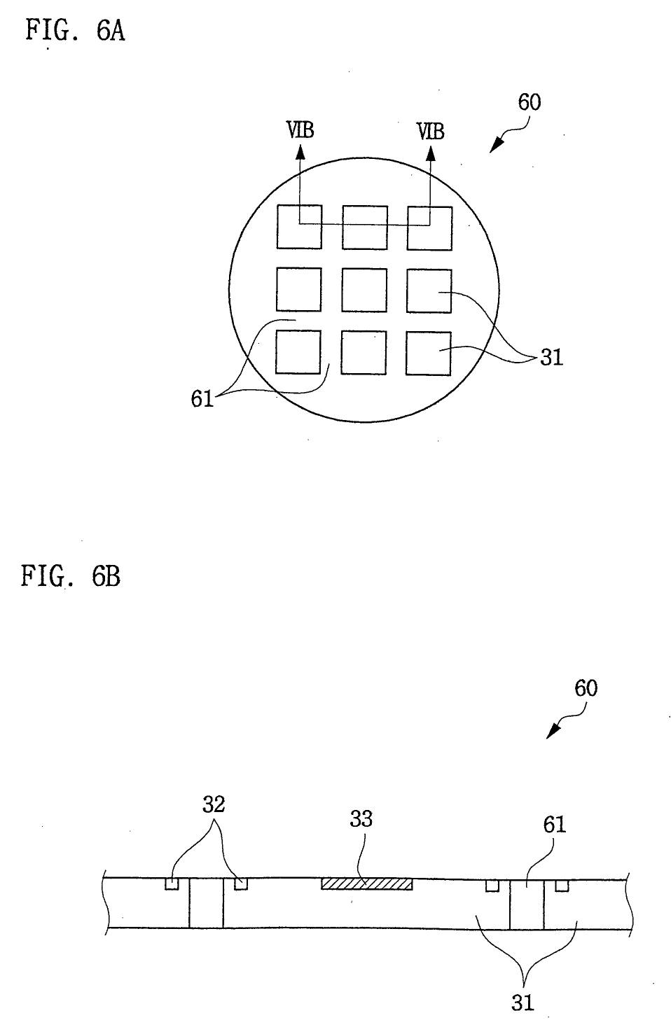

FIGS. 6A to 9 show in sequence a method of fabricating an ultrathin module in accordance with the present invention. In the following description of the fabrication method, the structure of the ultrathin module will also be described more fully.

Referring to FIGS. 6A and 6B, first, a wafer 60 is provided. The wafer 60 includes a number of semiconductor device chips 31 formed on a silicon substrate. Scribe lanes 61 extend in orthogonal directions between the adjacent individual chips 31. As discussed above, each semiconductor chip 31 comprises a special kind of device such as an image sensor or a MEMS device. As mentioned earlier, the I/O pads 32 are arranged along the periphery of the active surface of the chip 31, and the central portion of the active surface has a specific region 33 that must be protected from the external environment.

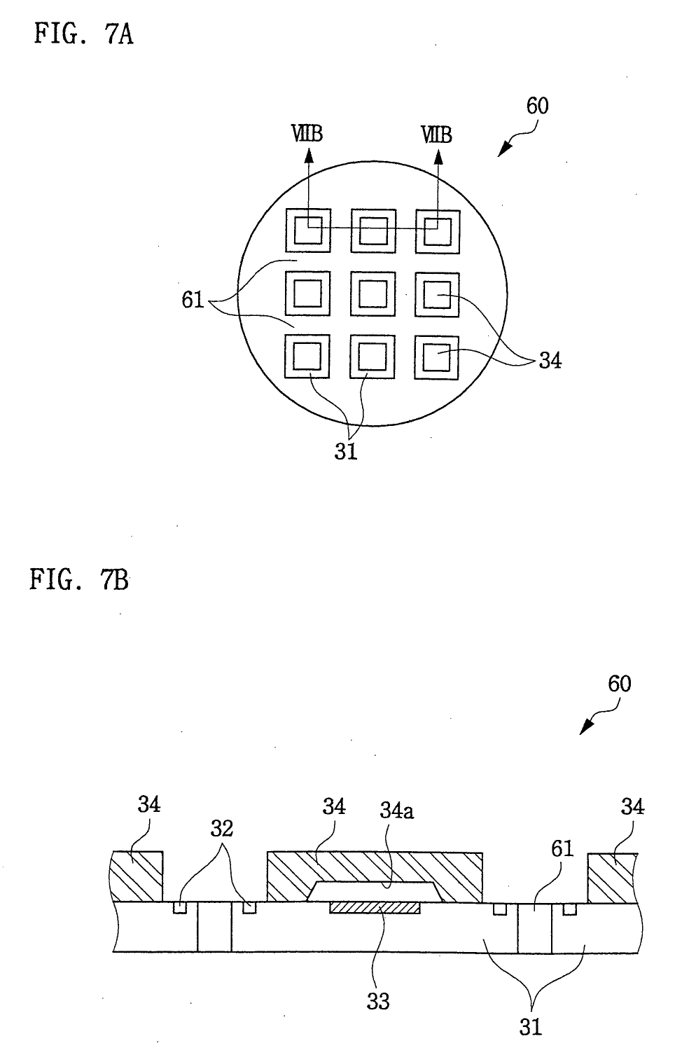

After the wafer 60 is provided, the chip covers 34 are directly attached to the chips 31. More specifically, as shown in FIGS. 7A and 7B, a chip cover 34 is directly attached to the active surface of each chip 31. Note, this process of attaching the chip cover 34 is carried out simultaneously for all of the chips 31 of the wafer 60. Furthermore, each chip cover 34 has a concavity provided in a central part of a lower surface thereof. The concavity is large enough to accommodate the specific region 33 of the chip 31 but the chip cover 34 itself does not cover the I/O pads 32. The concavity 34a of the chip cover 34 may be formed by one of several well-known techniques such as mechanical cutting, laser cutting, etching, or molding techniques. If the chip cover 34 is merely used as both a cover and an infrared rays light filter, the shape of the chip cover 34 is not limited. However, if the chip cover 34 is used as a lens assembly as well, the portion of the chip cover 34 defining the concavity must have the shape of a lens.

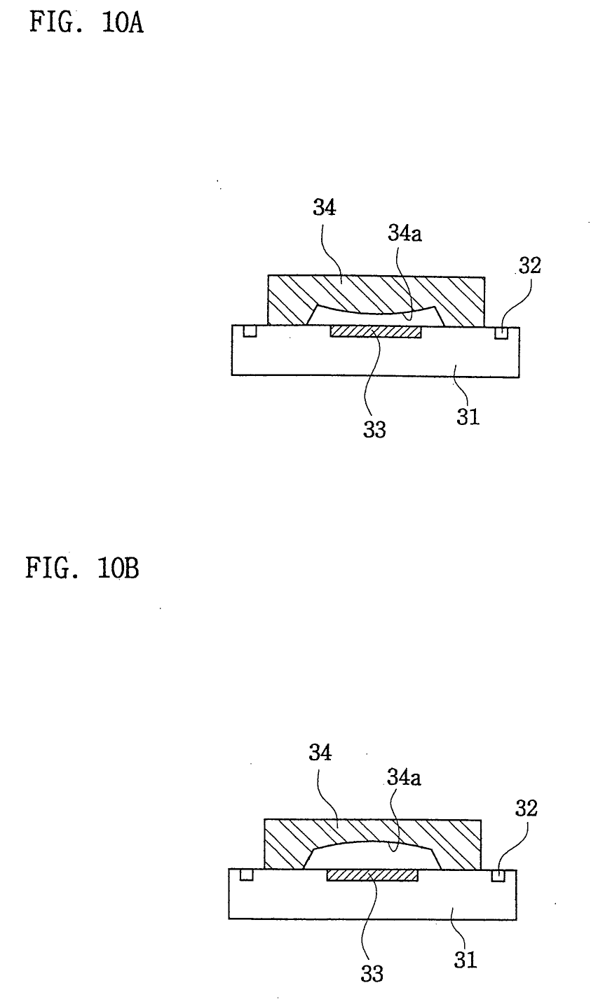

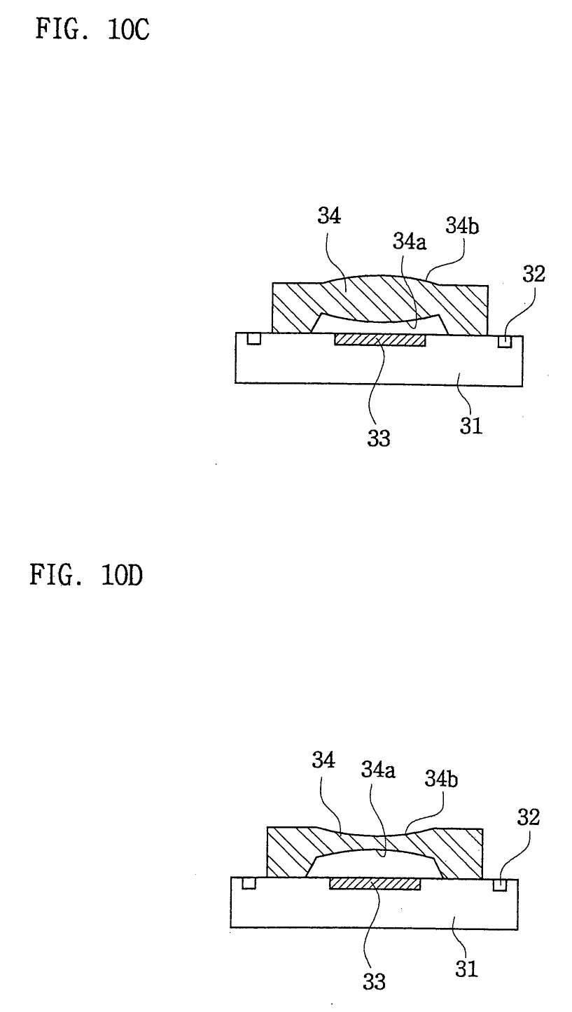

FIGS. 10A to 10D show several examples of the chip cover 34. As shown in FIGS. 10A and 10B, the chip cover 34 may have a portion that forms a plano-convex lens or a plano-concave lens. In these cases, the surface 34a of the chip cover 34 that defines the bottom of the concavity is curved. Alternatively, as shown in FIGS. 10C and 10D, the chip cover 34 may have a portion that forms a bi-convex lens or a bi-concave lens. In either of these cases, both a top surface 34b as well as the surface 34a of the chip cover 34 that defines the bottom of the concavity are curved.

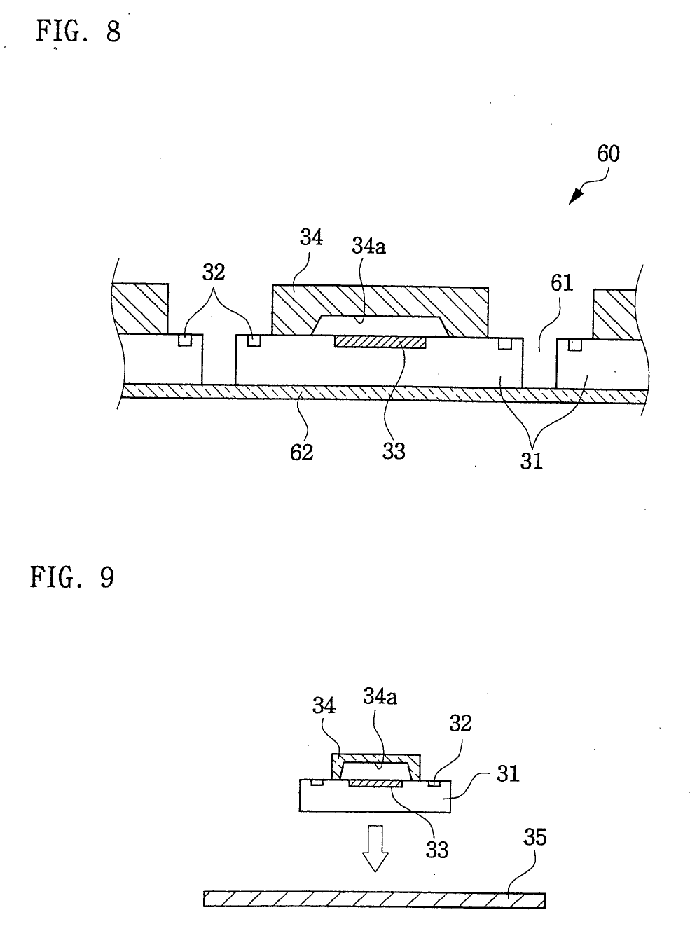

After the chip covers 34 are directly attached to the individual chips 31, respectively, the wafer 60 is cut to separate the individual chips 31 from one another. To this end, as shown in FIG. 8, the wafer 60 is temporarily supported by an adhesive tape 62 attached to a bottom surface of the wafer 60. Then the wafer 60 is subjected to a typical wafer slicing process in which a cutting tool (not shown), such as a diamond wheel or a laser cutter, slices the wafer 60 along the scribe lanes 61. The individual chips 31 are therefore separated from each other while remaining attached to the adhesive tape 62. In general, the wafer slicing process may often produce silicon particles and dust. However, the chip covers 34 protect the specific regions 33 of the chips 31 from such pollution, and from stains which could otherwise form when the wafer is cleaned with deionized wafer after the slicing process.

Next, a chip attaching process is implemented as shown in FIG. 9. In this process, each individual chip 31 is attached to a module substrate 35 (or lead frame 45 as shown in FIG. 4). In this process, a chip-transferring tool (not shown), such as a vacuum chuck, secures the chip 31 using a vacuum and detaches the chip 31 from the adhesive tape (62 in FIG. 8). Then the vacuum chuck transfers the chip 31 to the module substrate 35 (or lead frame 45) and presses the chip 31 down onto the module substrate 35 (or lead frame 45). Also, during this chip-attaching process, the chip cover 34 protects the specific region 33 from mechanical shocks.

Subsequently, a wire-bonding process is performed. In fabricating the embodiments of FIGS. 3 and 5, the I/O pads 32 are wired to the module substrate 35 by the wire-bonding process. On the other hand, in fabricating the embodiment of FIG. 4, the I/O pads 32 are wired to the lead frame 45. Finally, in fabricating the embodiments of FIGS. 3 and 4, a molding process is performed to form the body of plastic resin 37. In fabricating the embodiment of FIG. 5, the housing 57 is attached to the module substrate 35.

As discussed above, the ultrathin module according to the present invention is particularly useful for special types of semiconductor device chips such as image sensor device chips or MEMS device chips. As discussed above, the ultrathin module of the invention is characterized by a chip cover that is directly attached to the chip and can serve as a lens assembly as well as an infrared light filter. This unique configuration minimizes the thickness required of the module and hence, the size and weight of the final products that incorporate the module.

Moreover, incident light should be allowed to arrive at the light-sensing area of an image sensor device chip without obstruction. And, a MEMS device chip should have a space that allows the mechanical elements of the chip to a operate freely. The module structure of the present invention satisfies such specialized requirements of the image sensor device and MEMS device chips.

In addition, the fabrication method of the invention is characterized by a step of attaching the chip cover prior to the slicing of the wafer. This allows the specific region of the chip to be protected from being contaminated with silicon particles and dust produced during the wafer slicing process. This also prevents the specific region of the chip from being stained by deionized wafer used to clean the wafer after the slicing process. Furthermore, the fabrication method of the invention may employ a molding process because the specific region of the chip is completely protected in advance of the molding process. This facilitates the mass production of the modules and hence, the retrenchment of production cost.

Finally, although this invention has been particularly shown and described with reference to the preferred embodiments thereof, it will be understood by those skilled in the art that various changes in form and details may be made thereto without departing from the true spirit and scope of the invention as defined by the appended claims.

What is claimed is:

1. An ultrathin module comprising:
a semiconductor chip having an active surface, a specific region located at a central portion of the active surface, and input/output pads disposed along the periphery of the active surface;
a module substrate supporting the semiconductor chip, said chip being directly attached to the module substrate and electrically coupled thereto; and
a chip cover directly attached to the active surface of the semiconductor chip, said chip cover having a lower surface that faces the chip, and a cavity in a central part of said lower surface, the cavity being disposed over and spanning the specific region of the active surface of the semiconductor chip, and the lower surface of said chip cover having an outer edge terminating within said periphery of the active surface of the chip so as to not cover the input/output pads.

2. The module of claim 1, wherein the semiconductor chip includes an image sensor.

3. The module of claim 2, wherein the specific region includes a light-sensing area.

4. The module of claim 1, wherein the semiconductor chip includes a micro-electro-mechanical system (MEMS) device.

5. The module of claim 4, wherein the specific region includes mechanical elements.

6. The module of claim 1, wherein the module substrate is a printed circuit board, a lead frame, a ceramic substrate or a film having circuitry thereon.

7. The module of claim 1, wherein the chip cover is of transparent material.

8. The module of claim 7, wherein said material of the chip cover is selected from the group consisting of glass, transparent resin, and transparent metal oxide.

9. The module of claim 7, wherein the chip cover contains or is coated with metal ions.

10. The module of claim 1, wherein the chip cover is of translucent or opaque material.

11. The module of claim 10, wherein the chip cover is of plastic or ceramics.

12. The module of claim 1, and further comprising a body of plastic resin covering the semiconductor chip, an upper surface of the chip cover being exposed by said body of the plastic resin.

13. The module of claim 1, and further comprising a module housing covering the semiconductor chip, attached to the module substrate, and having a lens assembly lying directly over the chip cover.

14. The module of claim 1, wherein a portion of the chip cover overlying said specific region has a curved surface such that said portion of the chip cover has the form of a lens.

15. The module of claim 1, wherein the chip cover comprises material that filters infrared rays.

16. An ultrathin image sensor module comprising:
an image sensor chip having an active surface, a light-sensing area located at a central portion of the active surface, and input/output pads disposed along the periphery of the active surface;
a module substrate supporting the image sensor chip, the image sensor chip being directly attached and electrically coupled to said substrate; and
a chip cover directly attached to the active surface of the image sensor chip, said chip cover having a lower surface that faces the chip, and a cavity in a central part of said lower surface, the cavity being disposed over and spanning the light-sensing area of the chip, the lower surface of said chip cover having an outer edge terminating within said periphery of the active surface of the chip so as to not cover the input/output pads, and said chip cover comprising material that filters infrared rays.

17. The module of claim 16, wherein a portion of the chip cover overlying said light-sensing area has a curved surface such that said portion of the chip cover has the form of a lens.

18. The module of claim 16, wherein said chip cover comprises material selected from the group consisting of glass, transparent resin, and transparent metal oxide.

19. The module of claim 18, wherein the chip cover contains or is coated with metal ions.

20. An ultrathin module comprising:
a semiconductor chip having an active surface, a specific region located at a central portion of the active surface, and input/output pads disposed along the periphery of the active surface;
a chip cover directly attached to the active surface of the semiconductor chip, said chip cover having a lower surface that faces the chip, and a cavity in a central part of said lower surface, the cavity being disposed over and spanning the specific region of the active surface of the semiconductor chip, and the lower surface of said chip cover having an outer edge terminating within said periphery of the active surface of the chip so as to not cover the input/output pads; and
a body of plastic resin in which the semiconductor chip is embedded, an upper surface of the chip cover being exposed by said body of the plastic resin.

21. The module of claim 20, and further comprising a lead frame embedded in said body of plastic resin, said lead frame having a plurality of leads, and said input/output pads being electrically coupled to said lead frame.

22. The module of claim 21, wherein said lead frame further includes a chip-supporting pad supporting said semiconductor chip.

23. The module of claim 20, and further comprising a module substrate supporting the semiconductor chip, and bonding wires extending through said body of plastic resin from said input/output pads to said module substrate.

24. A method of fabricating an ultrathin module, the method comprising:
providing a wafer including a number of semiconductor chips each having an active surface, a specific region located at a central portion of said active surface, and input/output pads disposed along the periphery of the active surface;
directly attaching a respective chip cover, having a lower surface and a cavity in a central part of said lower surface, to the active surface of each of the semiconductor chips such that the cavity is located over and is open to the specific region while the input/output pads are left exposed at the outside of the chip cover;
subsequently slicing the wafer to separate the semiconductor chips from each other; and
subsequently directly attaching each semiconductor chip to a substrate.

25. The method of claim 24, and further comprising embedding the semiconductor chip in a body of plastic resin while leaving an upper surface of the semiconductor chip exposed at the outside of the body of plastic resin.

26. The method of claim 24, and further comprising attaching a module housing, having a lens assembly, to the substrate so as to cover the semiconductor chip and position the lens assembly over the specific region of the semiconductor chip.
